(19) United States
(12) Patent Application Publication
(10) Pub. No.: US 2013/0194746 A1
(43) Pub. Date: Aug. 1, 2013

(54) SYSTEM AND METHOD FOR MANAGING OUTPUT ENERGY LEVELS

(71) Applicant: Ian Lockerbie, Calgary (CA)

(72) Inventor: Ian Lockerbie, Calgary (CA)

(73) Assignee: NOVATEL WIRELESS, INC., San Diego, CA (US)

(21) Appl. No.: 13/361,836

(22) Filed: Jan. 30, 2012

(51) Int. Cl. H05K 7/20

(52) U.S. Cl. 361/679.48; 361/714; 361/679.54; 361/695

(57) ABSTRACT

Systems and methods are provided for controlling output energy levels in wireless communications devices, such as wireless USB modems, while optimizing performance of the wireless communications devices. Controlling output energy levels includes controlling specific absorption rate (SAR) levels and heat levels generated by one or more radiating elements in a wireless communications device. Controlling output energy levels is achieved by integrating one or more radiating elements in a movable device, such a fan and/or by incorporating a moving reflector element, such as a fan, proximate to one or more radiating elements. Integrating the one or more radiating elements in, e.g., a fan, or by using a fan near the one or more radiating elements, the radiation pattern resulting from the output energy may be spatially averaged and/or dithered, reducing SAR levels and allowing for excessive output heat energy to be vented and/or one or more radiating elements to be cooled.

### TECHNICAL FIELD

The present invention relates generally to wireless communication devices and, more particularly, to systems and methods for managing output energy levels, i.e., specific absorption rate (SAR) levels to comply with regulatory restrictions without lowering output power, and heat energy levels to address excessive heat output.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

Portable/wireless communication devices commonly transmit radio frequency (RF) signals through an antenna. Such communication devices may be used in a variety of manners and in a variety of conditions. Government regulations often require such devices to satisfy certain criteria associated with exposure.

In particular, the Federal Communications Commission (FCC) has expressed growing concern about external antennas and their Specific Absorption Rate (SAR) effects. Thus, the FCC has adopted limits for safe exposure to RF energy given in terms of SAR units, a measure of the amount of RF energy absorbed by the body when using a device, such as a mobile phone. For example, the FCC requires mobile phone manufacturers to ensure that their phones comply with these objective limits for safe exposure by operating at or below the desired SAR levels.

The FCC has also set forth rules concerning SAR levels of devices that may utilize one or more antennas, such as host devices that employ embedded modems, or wireless Universal Serial Bus (USB) modems. Even when body tissue can be moved further away from a radiating source, regulatory requirements still exist when exposure may occur at distances of over 20 cm from body tissue, i.e., maximum permissible exposure (MPE) limits. In order to comply with regulations of government agencies, such as the FCC, communication devices must be tested to ensure that the SAR levels from such devices are within acceptable levels.

More recently, the FCC has changed the way that SAR effects are measured with respect to USB stick/dongle communications devices that emit RF energy, such as USB modems with configurations that include, but are not limited to, straight USB sticks, swivel USB sticks, fixed angular USB sticks, etc. In particular, and until recently, the FCC required devices having one or more radiating elements to be tested at a separation of 1.5 cm between the device and a phantom simulating human body tissue, but now requires that the separation distance in such tests be reduced to 0.5 cm. The shorter test separation distance presents issues for conventional USB devices in that such conventional USB devices are likely incapable of passing the updated SAR measurement requirements as set forth by the FCC in OET Bulletin 65 (Supplement C).

Thus, to ensure compliance with the aforementioned radiation exposure requirements, tradeoffs are made between complying with such regulations and aesthetic and performance considerations. Some device manufacturers have resorted to increasing the physical form factor/envelope of their products in order to maintain a certain distance between a user and a device/radiating element. For example, certain devices are designed with a “SAR bubble” that is added to, e.g., plastic housings, to increase the separation between a device user and a radiating element. Moreover, manufacturers have been forced to implement contingency plans during the industrial design phase to account for cases where SAR requirements cannot be met.

Further still, thermal issues may arise, especially in small form factor devices. Such thermal issues, e.g., the excessive emission of heat from a radiating element/device, can necessitate the need for a some mechanism to vent excess heat or cool the device, where the excess heat may possibly lead to unacceptably high device temperatures during use.

### SUMMARY

Various aspects of examples of the invention are set out in the claims.

According to a first aspect, a method for managing output energy levels of a device, comprises outputting energy from a radiating element of the device. The method further comprises dissipating effects of the output energy by moving the radiating element relative to a housing of the device.

According to a second aspect, a computer-readable memory includes computer executable instructions, the computer executable instructions, which when executed by a processor, cause an apparatus to: output energy from a radiating element of the device; and dissipate effects of the output energy by moving the radiating element relative to a housing of the device.

According to a third aspect, an apparatus comprises at least one processor and at least one memory. The at least one memory includes computer program code, the at least one memory and the computer program code configured to, with the at least one processor, cause the apparatus to perform at least the following: output energy from a radiating element of the device; and dissipate effects of the output energy by moving the radiating element relative to a housing of the device.

According to a fourth aspect, a method for managing output energy levels of a device, comprises outputting energy from a radiating element of the device. The method further comprises dissipating effects of the output energy by moving a reflector element proximate to a radiating element of the device.

According to a fifth aspect, a computer-readable memory includes computer executable instructions, the computer executable instructions, which when executed by a processor, cause an apparatus to: output energy from a radiating element of the device; and effects of the output energy by moving a reflector element proximate to a radiating element of the device.

According to a sixth aspect, an apparatus comprises at least one processor and at least one memory. The at least one memory includes computer program code, the at least one memory and the computer program code configured to, with the at least one processor, cause the apparatus to perform at least the following: output energy from a radiating element of the device; and effects of the output energy by moving a reflector element proximate to a radiating element of the device.

### BRIEF DESCRIPTION OF THE DRAWINGS

For a more complete understanding of example embodiments, reference is now made to the following descriptions taken in connection with the accompanying drawings in which:

FIG. 1 illustrates an exemplary wireless communications device with a radiating element;

FIG. 2 is a schematic representation of the exemplary wireless communications device of FIG. 1;

FIG. 3 is an exemplary implementation of a radiating element configured in accordance with one embodiment of the present application;

FIG. 4 is a schematic representation of an exemplary wireless communications device in which a radiating element configured in accordance with one embodiment of the present application is implemented;

FIG. 5 is a schematic representation of an exemplary wireless communications device in which a reflector element is implemented in accordance with one embodiment of the present application; and

FIG. 6 is a flow chart illustrating exemplary processes performed in accordance with various embodiments to dissipate the effects of output energy in accordance with one embodiment of the present application; and

FIG. 7 is a flow chart illustrating exemplary processes performed in accordance with various embodiments to dissipate the effects of output energy in accordance with another embodiment of the present application.

### DETAILED DESCRIPTION OF THE DRAWINGS

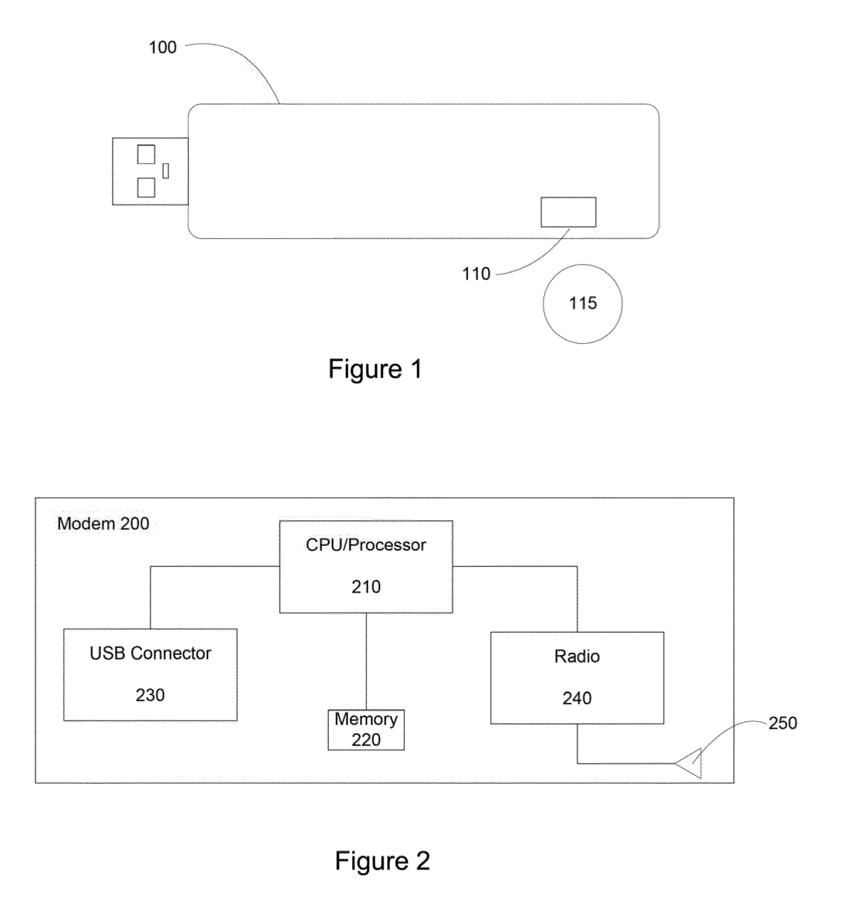

Example embodiments and their potential advantages are understood by referring to FIGS. 1-7 of the drawings.

As discussed above, tradeoffs are often made regarding design and performance considerations of a wireless communications device, such as a USB modem, in order to comply with SAR regulations. Once such performance tradeoff is output/radiated power. That is, complying with SAR regulations can lead to limits being placed on a maximum power output of a module. Limiting the output power of a module can lead to a reduction in the radiated power of the module, which in turn, can lead to less than optimal performance. For example, lowering the output power may ultimately result in lower data rates and/or dropped connections. Despite such drawbacks, power reduction is a preferred method of complying with SAR regulations as antenna/antenna system redesign at a host device can be costly and/or difficult.

Another tradeoff may result in the case of USB modems, where, as alluded to previously, the USB modem housing is altered (whether in material, size, design, etc.) to increase the distance between a user operating a USB modem and one or more antennas of the USB modem. In certain cases, complying with SAR regulations may require, in accordance with conventional methods, altering physical aspects of a USB modem to increase the distance between a user and a radiating antenna, as well as reducing output power. However, altering physical aspects of an embedded modem is not preferable as consumers often prefer, and design trends are moving to, smaller form factor devices. Also, technology specifications, such as the 3^{rd} Generation Partnership Project (3GPP) conducted power requirements, manufacturer Total Radiated Power (TRP) requirements, etc., may only provide a narrow margin by which power output can be reduced.

Addressing SAR level failures through rigorous antenna modeling and/or design/redesign, and then implementing a “patch” to address any design failures by altering the industrial design of a product, such as USB modem, is both time consuming and risky. For example, manufacturers often have little to no design margin to guarantee that a product, as envisioned, can be developed. Further still, and as also previously discussed, thermal issues can arise in small form factor devices, thus potentially limiting the extent to which device size can be reduced in accordance with current design trends.

SAR levels are dependent upon output power of a device, e.g., a USB modem, in particular, the radiating element therein, such as a radiating antenna. Accordingly, various embodiments of the present invention are directed to controlling RF exposure from wireless communications devices by implementing a movable radiating element and/or a movable reflector element used in conjunction with either a movable or stationary radiating element. Moreover, the movable radiating element and/or movable reflector element may be implemented as/embodied in a fan or fan-like structure to provide a mechanism for venting excess heat/cooling the radiating element and/or device.

FIG. 1 illustrates an exemplary wireless communications device 100 having a transmission (Tx) antenna 110. The device 100 may be a USB stick modem configured for connection to a host device, such as a laptop computer. FIG. 2 illustrates a modem 200, which provides a schematic representation of the device 100 illustrated in FIG. 1. Modem 200 may include at least one central processing unit (CPU)/processor 210 and at least one memory unit 220. Modem 200 may further include a USB connector 230 allowing the modem 200 to be connected to a host device. Moreover, the modem 200 includes at least one radio 240, the radio 240 comprising a transmitter and receiver. Connected to each of the at least one radio 240 is an antenna 250.

In a device with at least one transmitter/radio, such as device 100, transmit power peaks occur. For example, if device 100 is transmitting on Tx antenna 110, a field peak near that antenna results, as shown by field 115. SAR measurements in this context may be thought of as being analogous to thermal measurements in the sense that if there is a point thermal source, the point thermal source will create a hot spot. Thus, SAR measurements taken if human tissue was proximate to the Tx antenna 110 (and resulting field 115), would indicate a hot spot (peak SAR) in this area/field that could potentially surpass regulatory requirements.

Moreover, and in addition to the thermal analogy, output energy in the form of actual thermal energy/heat may dissipated at or near the Tx antenna 110/field 115 resulting from the operation of the radio and/or Tx antenna. That is, to generate the requisite output power needed for desired transmission characteristics, the radio/Tx antenna may operate in a manner that generates a certain (and at times, unacceptable) amount of heat. Excessive or unacceptable heat levels may, e.g., disrupt optimal operating characteristics of the radio/Tx antenna, shorten the lifespan of the radio/Tx antenna, etc. Moreover, the unacceptably high temperatures may also be detrimental to the comfort and/or safety of a user utilizing a device having such a radio/Tx antenna with excessive heat output.

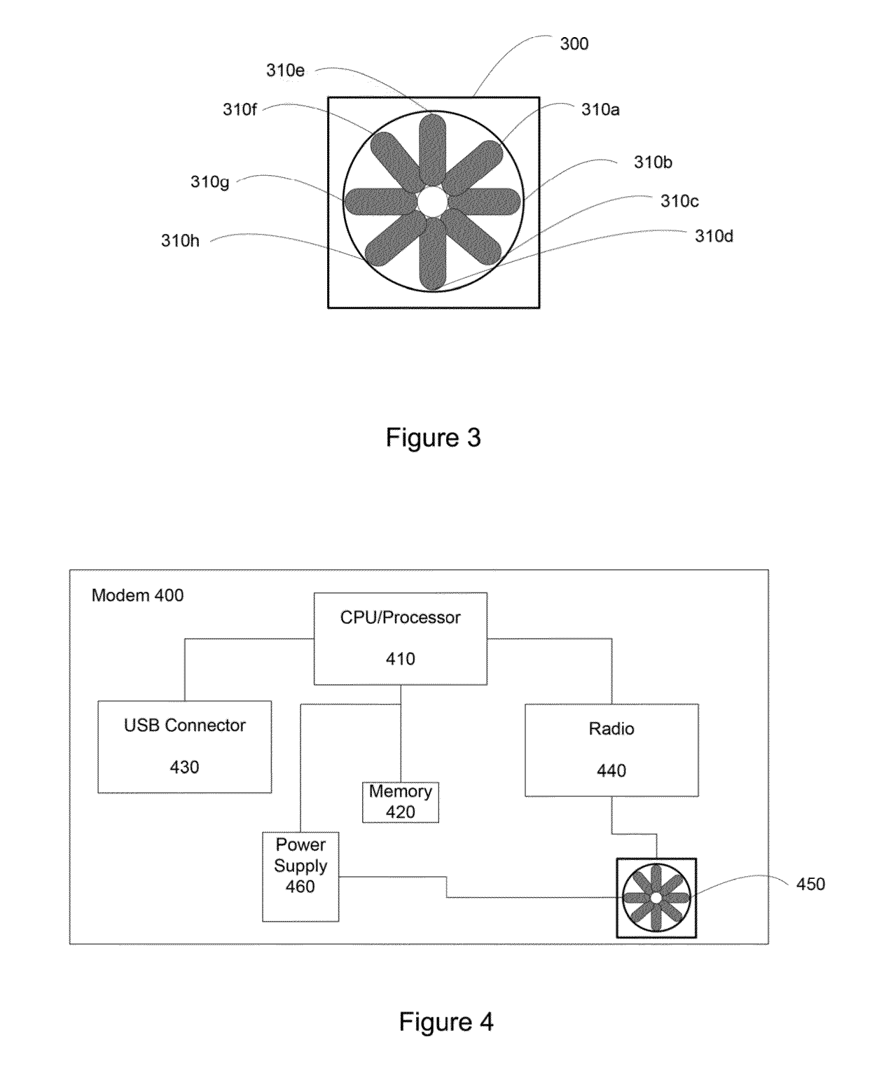

To alleviate such issues, and in accordance with one embodiment, a Tx antenna, such as Tx antenna 110 or Tx antenna 250 of FIGS. 1 and 2, respectively, may be configured as a moving radiating element. That is, a radiating element such as a Tx antenna may be configured to move relative to, e.g., a device housing, in order to spatially average SAR hotspots over an area relative to/dependent upon the motion of the radiating element. For example, a Tx antenna may be implemented as a fan 300, such as that illustrated in FIG. 3, where radiating elements of the Tx antenna would be incorporated into or configured to move as one or more fan blades, such as elements 300a-300h. Alternatively, one or more radiating elements may be integral to some other movable part or aspect of a fan or fan-like mechanism. Because the radiating element(s) moves, the radiation pattern resulting from the output of power from the radiating element(s) is spatially averaged over an area, which in turn reduces peak SAR levels, especially at any one location. Furthermore, and due to the ability to spatially average SAR levels, device manufacturers are afforded a greater design margin for both resulting SAR levels, as well as a higher allowable output power.

The fan 300, in addition to spatially averaging radiation, provides a cooling and/or venting mechanism should the Tx antenna and/or associated radio emit an excessive amount of heat. Control of the fan may be effectuated via circuitry or logic control and/or an appropriate algorithm. For example, a temperature sensor may be implemented in/near the radiating element, and upon sensing excessive heat, may initiate a process to power on the fan. It should be noted that a temperature sensor is not necessarily needed as the fan 300 may merely be configured to constantly operate, or periodically turn on and off according to predetermined timing sequence.

FIG. 4 is a schematic representation of a modem 400 in which a radiating element, such as a Tx antenna, is implemented as/in a fan. Modem 400, like modem 200 of FIG. 2, may include at least one central processing unit (CPU)/processor 410 and at least one memory unit 420. Modem 400 may further include a USB connector 430 allowing the modem 400 to be connected to a host device. Moreover, the modem 400 includes at least one radio 440, the radio 440 comprising a transmitter and receiver. Connected to each of the at least one radio 440 is a fan 450 that includes one or more radiating elements and acts as a Tx antenna.

In accordance with one embodiment, initiating a process to power on a fan, such as fan 450, involves the CPU/processor 410 of the modem 400 powering on the fan 450 via power supply 460. It should be noted that the power supply 460 may be a power supply that provides power to the modem 400 for its normal operation, a power supply implemented solely for the purpose of providing power to the fan 450, or even a power supply of a host device (not shown) that is leveraged to operate the fan 450. Moreover, and in accordance with another aspect of the present invention, a separate CPU/processor may be implemented in the modem 400 (or a CPU/processor of a host device may be utilized) for controlling one or more of the cooling aspect and radiating aspect of the fan 450. Alternatively still, the separate CPU/processor may operate in conjunction with the CPU/processor 410 so that operation of the fan 450 as a cooling device and as a Tx antenna may be controlled substantially simultaneously and/or cooperatively.

In accordance with another embodiment of the present invention, a moving reflector element is implemented in a device with a radiating element. The moving reflector element may be located near a radiating element causing the resulting radiation pattern emanating from the radiating element to move in response to the movement of the reflector element. As previously described, a field peak near a radiating element such as a Tx antenna results due to the output of energy from the radiating element. Thus, SAR measurements taken if human tissue was proximate to such a radiating element, would indicate a hot spot (peak SAR) in this area/field that could potentially surpass regulatory requirements. Additionally, and as also described previously, actual thermal energy/heat may emanate at or near a radiating element/field peak resulting from the operation of the radiating element. Hence, the movement of the reflector element would dither the radiation pattern from the radiating element, yielding a lower peak SAR, and more averaged pattern of radiation energy, as well provide a mechanism to vent excessive heat generated by the radiating element and/or cool the radiating element/radio itself.

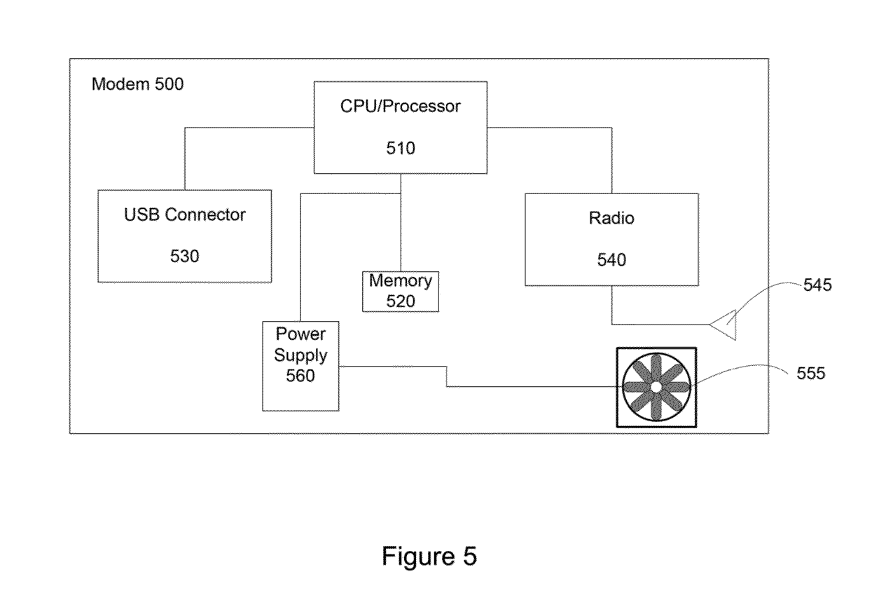

FIG. 5 is a schematic representation of a wireless device, such as a modem, 500 in which a moving reflector element is utilized to maintain and/or reduce resulting SAR levels. Modem 500 may include at least one central processing unit (CPU)/processor 510 and at least one memory unit 520. Modem 500 may further include a USB connector 530 allowing the modem 500 to be connected to a host device. Moreover, the modem 500 includes at least one radio 540, the radio 540 comprising a transmitter and receiver. Connected to each of the at least one radio 540 is an antenna 545 that includes one or more radiating elements for transmitting/receiving signals generated by/destined for the radio 540.

In accordance with one embodiment, a device such as a fan 555 may have one or more reflector elements incorporated into or on one or more fan blades. The fan 555 is located proximate to the antenna 545. The reflector elements may be any type of device, surface, material, or other element capable of reflecting electromagnetic waves. The reflector elements may be passive reflector, a corner reflector, a parabolic reflector, a flat reflector, etc. or any combination thereof. Additionally, parameters that can affect performance of the antenna 545, including but not limited to, e.g., aperture blockage, spillover, feed loss, desired output power, etc., may be taken into account when implementing and/or configuring the one or more reflector elements to provide the desired dithering/spatial averaging effect as well as provide the desired output power.

As previously described, initiating a process to power on the fan 555 involves the CPU/processor 510 of the modem 500 powering on the fan 555 via power supply 560. It should be noted that the power supply 560 may be a power supply that provides power to the modem 500 for its normal operation, a power supply implemented solely for the purpose of providing power to the fan 555, or even a power supply of a host device (not shown) that is leveraged to operate the fan 555. Moreover, and in accordance with another aspect of the present invention, a separate CPU/processor may be implemented in the modem 500 (or a CPU/processor of a host device may be utilized) for controlling one or more of the cooling aspect and radiating aspect of the fan 555. Alternatively still, the separate CPU/processor may operate in conjunction with the CPU/processor 510 so that operation of the fan 555 as a cooling device and as a reflector for a Tx antenna may be controlled substantially simultaneously and/or cooperatively.

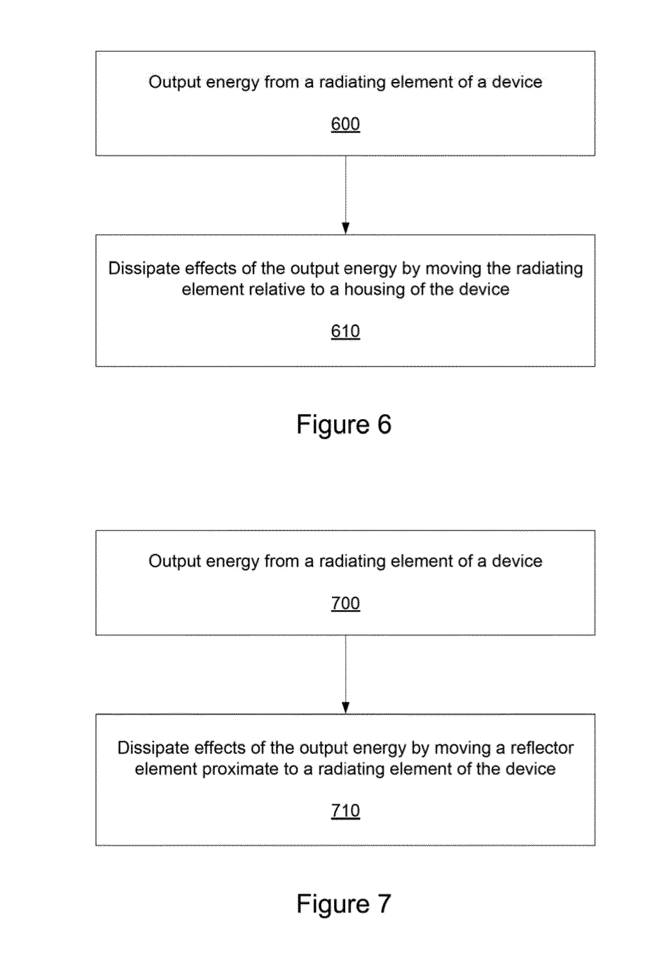

FIG. 6 illustrates exemplary processes performed in accordance with various embodiments of the present invention for controlling output energy levels. At 600, energy is output from a radiating element of a device, such as a wireless USB modem. The output energy may be, as described above, heat energy and/or RF energy. At 610, the effects of the output energy are dissipated by moving the radiating element relative to a housing of the device. That is, the radiating element(s) may be integrated into a fan device, the blades of the fan moving relative to housing of the device effectuating spatial averaging of the radiation pattern resulting from the radiating element, as well as venting heat from and/or cooling the radiating element.

FIG. 7 illustrates exemplary processes performed in accordance with various embodiments of the present invention for controlling output energy levels. At 700, energy is output from a radiating element of a device, such as a wireless USB modem. The output energy may be, as described above, heat energy and/or RF energy. At 710, the effects of the output energy are dissipated by moving a reflector element proximate to a radiating element of the device. That is, the reflector element may be, e.g., a fan device, the fan device operatively dithering the radiation pattern from the radiating element as well as venting heat from and/or cooling the radiating element.

It should be noted that although various embodiments of the present invention described herein involve implementation of a fan near or as one or more radiating elements to dither and/or effectuate spatial averaging of the radiation pattern of the one or more radiating elements, other implementations are contemplated in accordance with other embodiments. For example, a Tx antenna may be configured to “sweep” across a certain path or around a pivot point also resulting in spatial averaging of a radiation pattern instead of a focused SAR hot spot. A reflector element, such as a parabolic-shaped device may positioned near or integrated with a Tx antenna, where one or both the reflector element and the Tx antenna are movable with respect to the housing of a device in which the Tx antenna is incorporated. In other words, the above-described systems and methods of heat ventilation/cooling, SAR level spatial averaging/dithering are not intended to be limiting, but merely exemplary, and various embodiments of the present invention contemplate other radiating element and/or reflector element designs and configurations. Moreover, the aforementioned embodiments may also be combined in various manners.

Various embodiments of the present invention may be implemented in a system having multiple communication devices that can communicate through one or more networks. The system may comprise any combination of wired or wireless networks such as a mobile telephone network, a wireless Local Area Network (LAN), a Bluetooth personal area network, an Ethernet LAN, a wide area network, the Internet, etc.

Communication devices may include a mobile telephone, a personal digital assistant (PDA), a notebook computer, a wireless or embedded modem, etc. The communication devices may be located in a mode of transportation such as an automobile.

The communication devices may communicate using various transmission technologies such as Code Division Multiple Access (CDMA), Global System for Mobile Communications (GSM), Universal Mobile Telecommunications System (UMTS), Time Division Multiple Access (TDMA), Frequency Division Multiple Access (FDMA), Transmission Control Protocol/Internet Protocol (TCP/IP), Short Messaging Service (SMS), Multimedia Messaging Service (MMS), e-mail, Instant Messaging Service (IMS), Bluetooth, IEEE 802.11, Evolution-Data Optimized/Only (EVDO), Worldwide Interoperability for Microwave Access (WiMAX), etc.

An electronic device in accordance with embodiments of the present invention may include a display, a keypad for input, a microphone, an ear-piece, a battery, and an antenna. The device may further include radio interface circuitry, codec circuitry, a controller/CPU/processor and a memory.

Various embodiments described herein are described in the general context of method steps or processes, which may be implemented in one embodiment by a software program product or component, embodied in a machine-readable medium, including executable instructions, such as program code, executed by entities in networked environments. Generally, program modules may include routines, programs, objects, components, data structures, etc. that perform particular tasks or implement particular abstract data types. Executable instructions, associated data structures, and program modules represent examples of program code for executing steps of the methods disclosed herein. The particular sequence of such executable instructions or associated data structures represents examples of corresponding acts for implementing the functions described in such steps or processes.

Software implementations of various embodiments of the present invention can be accomplished with standard programming techniques with rule-based logic and other logic to accomplish various database searching steps or processes, correlation steps or processes, comparison steps or processes and decision steps or processes.

The foregoing description of various embodiments have been presented for purposes of illustration and description. The foregoing description is not intended to be exhaustive or to limit embodiments of the present invention to the precise form disclosed, and modifications and variations are possible in light of the above teachings or may be acquired from practice of various embodiments of the present invention. The embodiments discussed herein were chosen and described in order to explain the principles and the nature of various embodiments of the present invention and its practical application to enable one skilled in the art to utilize the present invention in various embodiments and with various modifications as are suited to the particular use contemplated. The features of the embodiments described herein may be combined in all possible combinations of methods, apparatus, modules, systems, and computer program products.

If desired, the different functions discussed herein may be performed in a different order and/or concurrently with each other. Furthermore, if desired, one or more of the above-described functions may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

1. A method for managing output energy levels of a device, comprising:
outputting energy from a radiating element of the device; and
dissipating effects of the output energy by moving the radiating element relative to a housing of the device.

2. The method of claim 1, wherein the energy output from the radiating element comprises at least one of heat and radiofrequency (RF) energy.

3. The method of claim 2, wherein the dissipating of the effects of the output energy comprises at least one of venting excess heat output from the radiating element and cooling the radiating element.

4. The method of claim 3, wherein the at least one of the venting of the excess heat output from the radiating element and the cooling of the radiating element is initiated pursuant to sensing of the heat energy via a temperature sensor.

5. The method of claim 2, wherein the dissipating of the effects of the output energy comprises spatially averaging a radiation pattern resulting from the outputting of the RF energy from the radiating element.

6. The method of claim 1, wherein the radiating element comprises a plurality of fan blades, each of the plurality of fan blades having incorporated therein a transmitting antenna element, and wherein the device comprises a wireless universal serial bus (USB) modem.

7. The method of claim 1 further comprising, balancing the dissipating of the effects of the output energy with a desired power level of the output energy.

8. A computer-readable memory including computer executable instructions, the computer executable instructions, which when executed by a processor, cause an apparatus to perform a method as claimed in claim 1.

9. An apparatus, comprising:
at least one processor; and
at least one memory including computer program code, the at least one memory and the computer program code configured to, with the at least one processor, cause the apparatus to perform at least the following:
output energy from a radiating element of the apparatus; and
dissipate effects of the output energy by moving the radiating element relative to a housing of the apparatus.

10. The apparatus of claim 9, wherein the energy output from the radiating element comprises at least one of heat and radiofrequency (RF) energy.

11. The apparatus of claim 10, wherein to perform the dissipating of the effects of the output energy, the at least one memory and the computer program code configured to, with the at least one processor, cause the apparatus to at least one of vent excess heat output from the radiating element and cool the radiating element.

12. The apparatus of claim 11, wherein the at least one of the venting of the excess heat output from the radiating element and the cooling of the radiating element is initiated pursuant to sensing of the heat energy via a temperature sensor.

13. The apparatus of claim 10, wherein to perform the dissipating of the effects of the output energy, the at least one memory and the computer program code configured to, with the at least one processor, cause the apparatus to spatially average a radiation pattern resulting from the outputting of the RF energy from the radiating element.

14. The apparatus of claim 9, wherein the radiating element comprises a plurality of fan blades, each of the plurality of fan blades having incorporated therein a transmitting antenna element, and wherein the apparatus comprises a wireless universal serial bus (USB) modem.

15. The apparatus of claim 9, wherein the at least one memory and the computer program code configured to, with the at least one processor, further cause the apparatus to balance the dissipating of the effects of the output energy with a desired power level of the output energy.

16. A method for managing output energy levels of a device, comprising:
outputting energy from a radiating element of the device; and
dissipating effects of the output energy by moving a reflector element proximate to a radiating element of the device.

17. The method of claim 16, wherein the energy output from the radiating element comprises at least one of heat and radiofrequency (RF) energy.

18. The method of claim 17, wherein the reflector element comprises a fan configured to at least one of vent excess heat output from the radiating element and cool the radiating element.

19. The method of claim 17, wherein the dissipating of the effects of the output energy comprises dithering a radiation pattern resulting from the outputting of the RF energy from the radiating element.

20. The method of claim 16, wherein the reflector element comprises a fan, the radiating element comprises a transmission antenna, and the device comprises a wireless universal serial bus (USB) modem.

21. A computer-readable memory including computer executable instructions, the computer executable instructions, which when executed by a processor, cause an apparatus to perform a method as claimed in claim 16.

22. An apparatus, comprising:
at least one processor; and
at least one memory including computer program code, the at least one memory and the computer program code configured to, with the at least one processor, cause the apparatus to perform at least the following:
output energy from a radiating element of the apparatus; and
dissipate effects of the output energy by moving a reflector element proximate to the radiating element.

23. The apparatus of claim 22, wherein the energy output from the radiating element comprises at least one of heat and radiofrequency (RF) energy.

24. The apparatus of claim 23, wherein the reflector element comprises a fan configured to at least one of vent excess heat output from the radiating element and cool the radiating element.

25. The apparatus of claim 23, wherein to perform the dissipating of the effects of the output energy, the at least one memory and the computer program code configured to, with the at least one processor, cause the apparatus to dither a radiation pattern resulting from the outputting of the RF energy from the radiating element.

26. The apparatus of claim 23, wherein the reflector element comprises a fan, the radiating element comprises a transmission antenna, and the apparatus comprises a wireless universal serial bus (USB) modem.
